(19) United States
(12) Patent Application Publication
(10) Pub. No.: US 2024/0411096 A1
(43) Pub. Date: Dec. 12, 2024

(54) OPTOELECTRONIC PACKAGE STRUCTURE

(71) Applicant: Advanced Semiconductor Engineering, Inc., Kaohsiung (TW)

(72) Inventors: Jr-Wei LIN, Kaohsiung (TW); Mei-Ju LU, Kaohsiung (TW); Sin-Yuan MU, Kaohsiung (TW)

(73) Assignee: Advanced Semiconductor Engineering, Inc., Kaohsiung (TW)

(21) Appl. No.: 18/208,226

(22) Filed: Jun. 9, 2023

(51) Int. Cl. G02B 6/43

(52) U.S. Cl. CPC G02B 6/43; H01L 24/13; H01L 24/14; H01L 24/16; H01L 24/32; H01L 24/73; H01L 2224/13024; H01L 2224/13139; H01L 2224/13144; H01L 2224/13147; H01L 2224/14181; H01L 2224/16225; H01L 2224/32145; H01L 2224/73253; H01L 2924/0132

(57) ABSTRACT

An optoelectronic package structure is provided. The optoelectronic package structure includes a first photonic component and an optical interposer. The optical interposer includes a plurality of optical paths and optically coupled to the first photonic component. The optical interposer is configured to switch between the optical paths for transmitting an optical signal from the first photonic component.

### BACKGROUND

### 1. Technical Field

The present disclosure relates generally to an optoelectronic package structure.

### 2. Description of the Related Art

A photonic component (e.g., a silicon-photonic chip) may be configured to transmit optical signals and be applicable to optical communication fields. Current photonic components receive optical signals through connection to optical fibers. However, it is a challenge to package multiple photonic components at different elevations and to communicate among said photonic components. Therefore, an improved optoelectronic package structure is called for.

### SUMMARY

In one or more arrangements, an optoelectronic package structure includes a first photonic component and an optical interposer. The optical interposer includes a plurality of optical paths and optically coupled to the first photonic component. The optical interposer is configured to switch between the optical paths for transmitting an optical signal from the first photonic component.

In one or more arrangements, an optoelectronic package structure includes a first photonic component and an optical interposer. The optical interposer has a first surface and a second surface opposite to the first surface. The optical interposer is configured to receive an optical signal from the first photonic component and switch between a first coupling region at the first surface and a second coupling region at the second surface to output the optical signal.

In one or more arrangements, an optoelectronic package structure includes a first photonic component, a second photonic component, and an optical interposer. The first photonic component and the second photonic component are disposed over a third photonic component. The optical interposer is configured to selectively optically couple the first photonic component to the second photonic component or the third photonic component.

### BRIEF DESCRIPTION OF THE DRAWINGS

Aspects of the present disclosure are best understood from the following detailed description when read with the accompanying drawings. It is noted that various features may not be drawn to scale, and the dimensions of the various features may be arbitrarily increased or reduced for clarity of discussion.

FIG. 1A is a cross-section of an optoelectronic package structure in accordance with some arrangements of the present disclosure.

FIG. 1B is a top view of an optoelectronic package structure in accordance with some arrangements of the present disclosure.

FIG. 2A is a cross-section of a portion of an optoelectronic package structure in accordance with some arrangements of the present disclosure.

FIG. 2B is a cross-section of a portion of an optoelectronic package structure in accordance with some arrangements of the present disclosure.

FIG. 2C is a cross-section of a portion of an optoelectronic package structure in accordance with some arrangements of the present disclosure.

FIG. 2D is a cross-section of a portion of an optoelectronic package structure in accordance with some arrangements of the present disclosure.

FIG. 2E is a cross-section of a portion of an optoelectronic package structure in accordance with some arrangements of the present disclosure.

FIG. 2F is a cross-section of a portion of an optoelectronic package structure in accordance with some arrangements of the present disclosure.

FIG. 3A is a top view of an optoelectronic package structure in accordance with some arrangements of the present disclosure.

FIG. 3B is a cross-section of an optoelectronic package structure in accordance with some arrangements of the present disclosure.

FIG. 3C is a cross-section of an optoelectronic package structure in accordance with some arrangements of the present disclosure.

FIG. 3D is a cross-section of an optoelectronic package structure in accordance with some arrangements of the present disclosure.

FIG. 4A is a top view of an optoelectronic package structure in accordance with some arrangements of the present disclosure.

FIG. 4B is a cross-section of an optoelectronic package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

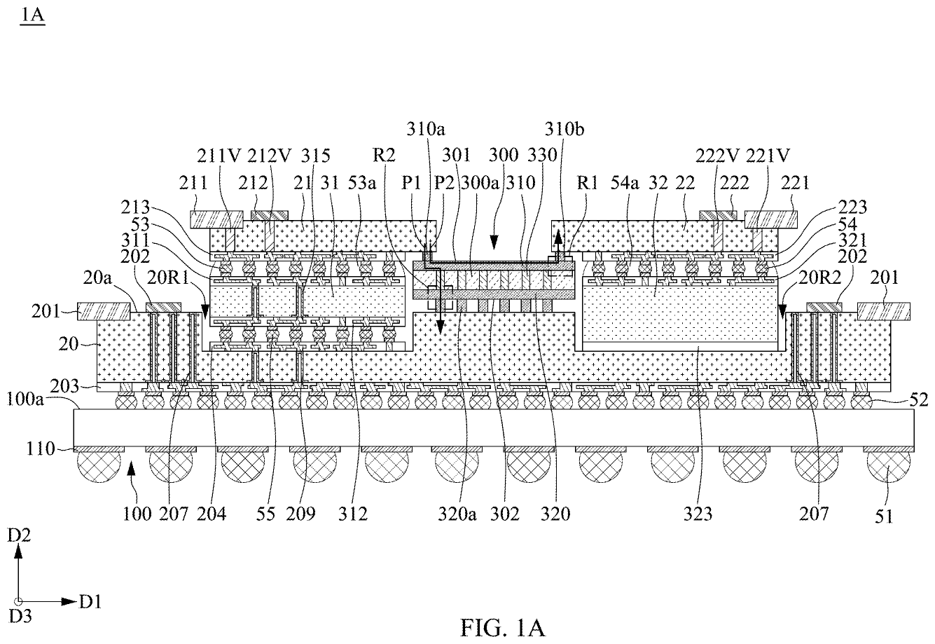

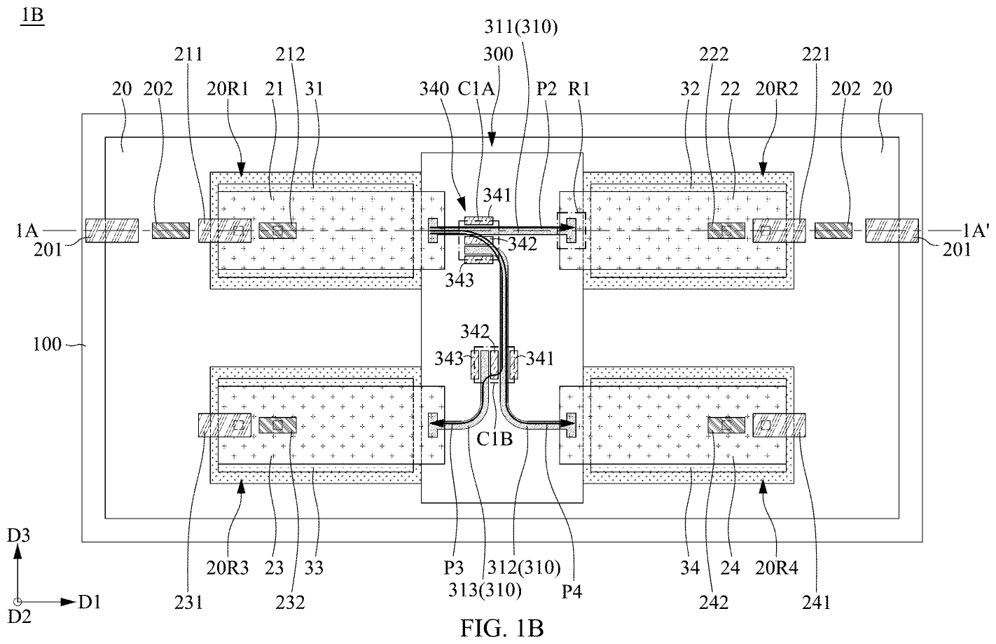

FIG. 1A is a cross-section of an optoelectronic package structure 1A in accordance with some arrangements of the present disclosure. The optoelectronic package structure 1A may include a carrier 100, photonic components 20, 21 and 22, electronic components 31 and 32, an optical interposer 300, and connection elements 51, 52, 53, 54 and 55. It should be noted that the numbers of the photonic components, electronic components, and/or other components may vary according to actual applications and are not limited thereto.

The carrier 100 may include, for example, a printed circuit board, such as a paper-based copper foil laminate, a composite copper foil laminate, or a polymer-impregnated glass-fiber-based copper foil laminate. The carrier 100 may include an interconnection structure, which may include such as a plurality of conductive traces and/or a plurality of conductive vias. The interconnection structure may include a redistribution layer (RDL) and/or a grounding element. In some arrangements, the carrier 100 may include a substrate, such as an organic substrate or a leadframe. In some arrangements, the carrier 100 may include a two-layer substrate which includes a core layer and a conductive material and/or structure disposed on an upper surface and a bottom surface of the carrier 100. The conductive material and/or structure may include a plurality of traces. The carrier 100 may include one or more conductive pads (e.g., conductive pads 110) in proximity to, adjacent to, or embedded in and exposed at an upper surface and/or a bottom surface of the carrier 100. The carrier 100 may include a solder resist (not shown) on the upper surface and/or the bottom surface of the carrier 100 to fully expose or to expose at least a portion of the conductive pads for electrical connections. The connection elements 51 may be disposed on the conductive pads 110. The connection elements 51 may be or include controlled collapse chip connection (C4) bumps, a ball grid array (BGA), or a land grid array (LGA). In some arrangements, the carrier 100 supports the photonic components 20, 21 and 23, the electronic components 31 and 32, and the optical interposer 300.

The photonic component 20 may be disposed over the carrier 100. In some arrangements, the photonic component 20 is electrically connected to the carrier 100 through the connection elements 52. The connection elements 52 may be or include conductive bumps, which may include gold (Au), silver (Ag), copper (Cu), another metal, a solder alloy, or a combination of two or more thereof. In some arrangements, the photonic component 20 has one or more recesses (e.g., recesses 20R1 and 20R2) recessed from an upper surface 20a of the photonic component 20. The photonic component 20 may include, but is not limited to, a photonic integrated circuit (PIC) and/or other suitable ICs. In some arrangements, the photonic component 20 includes optical components 201 and 202, redistribution layers (RDLs) 203 and 204, and conductive vias 207 and 209.

In some arrangements, the optical component 201 includes an optical fiber array component. In some arrangements, the optical fiber array component includes an integrated component including a plurality of fiber array units (FAUs). The optical component 201 may be connected to a waveguide (not shown) of the photonic component 20. The optical component 202 may include an optical emitting element that is configured to transmit an optical signal (or a processed optical signal). In some arrangements, the optical component 202 includes a laser diode. In some arrangements, the optical component 202 is electrically connected to the conductive vias 207. In some arrangements, the RDL 203 is electrically connected to the carrier 100 through the connection elements 52. In some arrangements, the RDL 204 is adjacent to the recess 20R1. In some arrangements, the RDL 204 is at least partially exposed to the recess 20R1. In some arrangements, the RDL 204 is electrically connected to the RDL 203 through the conductive vias 209.

The photonic component 21 may be disposed over the photonic component 20. The photonic component 21 may include, but is not limited to, a PIC and/or other suitable ICs. In some arrangements, the photonic component 21 includes optical components 211 and 212, a RDL 213, and optical vias 211V and 212V. The optical component 211 may be similar to the optical component 201, the optical component 212 may be similar to the optical component 202, and the description thereof is omitted hereinafter. In some arrangements, the optical component 211 is connected to the optical via 211V, and the optical component 212 is connected to the optical via 212V. In some arrangements, the optical vias 211V and 212V are configured to transmit optical signals but not electrical signals. The RDL 213 may be configured to transmit or receive an electrical signal to the carrier 100 and/or the electronic component 31. In some arrangements, the photonic component 21 (e.g., the RDL 213) may include an electrical-to-optical converter (not shown) and an optical-to-electrical converter (not shown) to convert an optical signal and/or an electrical signal.

The photonic component 22 may be disposed over the photonic component 20. The photonic component 22 may include, but is not limited to, a PIC and/or other suitable ICs. In some arrangements, the photonic component 22 includes optical components 221 and 222, a RDL 223, and optical vias 221V and 222V. The optical component 221 may be similar to the optical component 201, the optical component 222 may be similar to the optical component 202, and the description thereof is omitted hereinafter. In some arrangements, the optical component 221 is connected to the optical via 221V, and the optical component 222 is connected to the optical via 222V. In some arrangements, the optical vias 221V and 222V are configured to transmit optical signals but not electrical signals. The RDL 223 may be configured to transmit or receive an electrical signal to the carrier 100 and/or the electronic component 32. In some arrangements, the photonic component 22 (e.g., the RDL 223) may include an electrical-to-optical converter (not shown) and an optical-to-electrical converter (not shown) to convert an optical signal and/or an electrical signal. In some arrangements, the photonic component 21 and the photonic component 22 are arranged side by side.

The electronic component 31 may be at least partially embedded in the photonic component 20. In some arrangements, the electronic component 31 is at least partially disposed in the recess 20R1. In some arrangements, the electronic component 31 is electrically connected to the RDL 204 of the photonic component 20. In some arrangements, the electronic component 31 is configured to process an electrical signal (also referred to as “a first electrical signal”) from the photonic component 21 and an electrical signal (also referred to as “a second electrical signal”) from the photonic component 20.

In some arrangements, the electronic component 31 includes RDLs 311 and 312 and conductive vias 315. In some arrangements, the RDL 311 is electrically connected to the RDL 312 through the conductive vias 315. In some arrangements, the electronic component 31 is flip-chip bonded to the photonic component 21. In some arrangements, the RDL 311 is electrically connected to the RDL 213 of the photonic component 21 through connection elements 53. The connection elements 53 may be or include conductive bumps, which may include gold (Au), silver (Ag), copper (Cu), another metal, a solder alloy, or a combination of two or more thereof. The connection elements 53 may be covered by a protective element 53a, e.g., an underfill. In some arrangements, the RDL 312 is electrically connected to the RDL 204 of the photonic component 20 through connection elements 55. The connection elements 55 may be or include conductive bumps, which may include gold (Au), silver (Ag), copper (Cu), another metal, a solder alloy, or a combination of two or more thereof. In some arrangements, a power may be supplied to the electronic component 31 through the RDL 204 and the RDL 312.

The electronic component 32 may be at least partially embedded in the photonic component 20. In some arrangements, the electronic component 32 is at least partially disposed in the recess 20R2. In some arrangements, the electronic component 32 is configured to process an electrical signal from the photonic component 22. In some arrangements, the electronic component 32 includes a RDL 321. In some arrangements, the electronic component 32 is flip-chip bonded to the photonic component 22. In some arrangements, the RDL 321 is electrically connected to the RDL 223 of the photonic component 22 through connection elements 54. The connection elements 54 may be or include conductive bumps, which may include gold (Au), silver (Ag), copper (Cu), another metal, a solder alloy, or a combination of two or more thereof. The connection elements 54 may be covered by a protective element 54a, e.g., an underfill. In some arrangements, the electronic component 32 is attached to a bottom of the recess 20R2 of the photonic component 20 through an adhesive layer 323. The adhesive layer 323 may include an insulative adhesive material.

The optical interposer 300 may be disposed between the photonic component 21 and the photonic component 20. The optical interposer 300 may be disposed between the photonic component 22 and the photonic component 20. The optical interposer 300 may be configured to support the photonic components 21 and 22. In some arrangements, the optical interposer 300 is free from overlapping the recess 20R1 along a direction D2 (also referred to as “a vertical direction”) that is substantially perpendicular to a surface 100a of the carrier 100. In some arrangements, the optical interposer 300 is free from overlapping the recess 20R2 along the direction D2 (or the vertical direction).

The optical interposer 300 may have a surface 301 and a surface 302 opposite to the surface 301, and the optical interposer 300 is configured to receive an optical signal from a photonic component (e.g., the photonic components 20, 21 and 22) and switch between a coupling region R1 at the surface 301 and a coupling region R2 at the surface 302 to output the optical signal. For example, the optical interposer 300 may be configured to receive an optical signal from the photonic component 21 and switch between the coupling region R1 and the coupling region R2 at opposite surfaces 301 and 302 to output the optical signal. In some arrangements, the photonic component 20 is optically coupled to the coupling region R2.

In some arrangements, the optical interposer 300 includes a plurality of optical paths (e.g., optical paths P1 and P2) and optically coupled to a photonic component (e.g., the photonic components 20, 21 and 22), and the optical interposer 300 is configured to switch between the optical paths (e.g., the optical paths P1 and P2) for transmitting an optical signal from the photonic component. In some arrangements, the optical interposer 300 is configured to switch between the optical paths (e.g., the optical paths P1 and P2) for transmitting the optical signal from one of the photonic components (e.g., the photonic component 21) to one of the other photonic components (e.g., the photonic component 20 or the photonic component 22). In some arrangements, the optical path P1 extends along the direction D2 (or the vertical direction), and the optical path P2 extends along a direction D1 (also referred to as “a horizontal direction) that is substantially perpendicular to the direction D2. In some arrangements, the optical interposer 300 is configured to switch between the optical path P1 and the optical path P2 for transmitting an optical signal to the photonic component 20 or the photonic component 22.

In some arrangements, the optical interposer 300 includes a base layer 300a, waveguides 310 and 320, and one or more optical vias 330. The waveguides 310 and 320 may be disposed on or adjacent to opposite surfaces of the base layer 300a. The optical vias 330 may penetrate the base layer 300a. The base layer 300a may be or include glass, a semiconductor material, or one or more dielectric layers. For example, the base layer 300a may be an organic substrate or a two-layer substrate which includes a core layer and a conductive material and/or structure disposed on an upper surface and a bottom surface thereof.

In some arrangements, the waveguide 310 is adjacent to the surface 301. In some arrangements, the waveguide 310 includes the coupling region R1. In some arrangements, the waveguide 310 extends in the direction D1 (or the horizontal direction). In some arrangements, the optical path P1 and the optical path P2 partially overlap in the waveguide 310. In some arrangements, the waveguide 310 is configured to transmit an optical signal through the optical path P2 from the photonic component 21 to the photonic component 22. In some arrangements, the waveguide 310 is optically coupled to the photonic component 21 and the photonic component 22. In some arrangements, the waveguide 310 includes optical contacts 310a and 310b. The waveguide 310 may be optically coupled to the photonic component 21 through the optical contact 310a, and the waveguide 310 may be optically coupled to the photonic component 22 through the optical contact 310b. The optical contact 310b may define the coupling region R1.

The waveguide 310 may include or be made of silicon, silicon nitride (Si₃N₄), lithium niobate (LiNbO₃), lithium tantalite (LiTiO₃), or a combination thereof. In some arrangements, the waveguide 310 may have a refractive index equal or exceeding about 2.0, about 2.2, about 3, or about 3.5. In some arrangements, the waveguide 310 includes or is made of a material having an electrical optic coefficient greater than about 30 pm/V. In some arrangements, the waveguide 310 includes or is made of lithium niobate (LiNbO₃), lithium tantalite (LiTiO₃), or a combination thereof. In some arrangements, the horizontal portion of the waveguide 310 includes a material having an electrical optic coefficient greater than about 30 pm/V, and the optical contacts 310a and 310b include silicon, silicon nitride (Si₃N₄), lithium niobate (LiNbO₃), lithium tantalite (LiTiO₃), or a combination thereof.

In some arrangements, the waveguide 320 is adjacent to the surface 302. In some arrangements, the waveguide 320 includes the coupling region R2. In some arrangements, the waveguide 320 includes optical contacts 320a. The waveguide 320 may be optically coupled to the photonic component 20 through the optical contact 320a. One or more of the optical contacts 320a may define the coupling region R2. The waveguide 320 may include or be made of silicon, silicon nitride (Si₃N₄), lithium niobate (LiNbO₃), lithium tantalite (LiTiO₃), or a combination thereof.

In some arrangements, the optical via 330 is adjacent to the waveguide 310. In some arrangements, the optical via 330 extends in the direction D2 that is substantially perpendicular to the direction D1. In some arrangements, the optical via 330 extends between the waveguide 310 and the waveguide 320. In some arrangements, the optical via 330 extends between the surface 301 and the surface 302. In some arrangements, the optical via 330 defines the optical path P1, and the waveguide 310 defines the optical path P2. In some arrangements, the optical contact 310a, a portion of the horizontal portion of the waveguide 310, a portion of the horizontal portion of the waveguide 320, and at least one of the optical contacts 320a may define the optical path P1. In some arrangements, the waveguide 310 (e.g., the optical contacts 310a and 310b and the horizontal portion) may define the optical path P2. In some arrangements, the optical via 330 is configured to transmit the optical signal through the optical path P1 from the photonic component 21 to the photonic component 20.

In some arrangements, a depth of the electronic component 31 embedded in the photonic component 20 is configured to adjust a thickness of the optical interposer 300. In some arrangements, a depth of the electronic component 31 extending into the recess 20R1 of the photonic component 20 is configured to adjust a thickness of the optical interposer 300. The depth of the electronic component 31 embedded in the photonic component 20 or extending into the recess 20R1 may be adjusted to fit the thickness of the optical interposer 300. A depth of the recess 20R1 may be adjusted to alter the depth of the electronic component 31 embedded in the photonic component 20 or extending into the recess 20R1. In some arrangements, a depth of the recess 20R1 may be configured to adjust a depth of the electronic component 31 embedded in the photonic component 20 or extending into the recess 20R1. In some arrangements, a depth of the electronic component 32 embedded in the photonic component 20 is configured to adjust a thickness of the optical interposer 300. In some arrangements, a depth of the electronic component 32 extending into the recess 20R2 of the photonic component 20 is configured to adjust a thickness of the optical interposer 300. The depth of the electronic component 32 embedded in the photonic component 20 or extending into the recess 20R2 may be adjusted to fit the thickness of the optical interposer 300. A depth of the recess 20R2 may be adjusted to alter the depth of the electronic component 32 embedded in the photonic component 20 or extending into the recess 20R2. In some arrangements, a depth of the recess 20R2 may be configured to adjust a depth of the electronic component 32 embedded in the photonic component 20 or extending into the recess 20R2. According to some arrangements of the present disclosure, with the design of the recess of the photonic component 20 in which the electronic component may be embedded, the overall thickness of the optical interposer may be reduced, and thus the size of the optoelectronic package structure 1A may be reduced accordingly, particularly in the vertical direction (e.g., the direction D2).

FIG. 1B is a top view of an optoelectronic package structure 1B in accordance with some arrangements of the present disclosure. In some arrangements, FIG. 1A is a cross-section along a line 1A-1A′ in FIG. 1B. The optoelectronic package structure 1B may include a carrier 100, photonic components 20, 21, 22, 23 and 24, electronic components 31, 32, 33, and 34, and an optical interposer 300. It should be noted that the numbers of the photonic components, electronic components, and/or other components may vary according to actual applications and are not limited thereto.

In some arrangements, the photonic components 21, 22, 23 and 24 are disposed over the photonic component 20. In some arrangements, the photonic component 20 has recesses 20R1, 20R2, 20R3, and 20R4, and each of the electronic components 31, 32, 33, and 34 is at least partially disposed in each of the corresponding recesses 20R1, 20R2, 20R3, and 20R4. In some arrangements, the photonic component 23 includes optical components 231 and 232, and the photonic component 24 includes optical components 241 and 242. The photonic components 23 and 24 are similar to the photonic components 21 and 22, the optical components 231 and 232 are similar to the optical components 211 and 212, the optical components 241 and 242 are similar to the optical components 211 and 212, the electronic components 33 and 34 are similar to the electronic components 31 and 32, and the description thereof is omitted hereinafter.

In some arrangements, the optical interposer 300 is configured to selectively optically couple one of the photonic components 20, 21, 22, 23 and 24 to another one of the photonic components 20, 21, 22, 23 and 24. For example, the optical interposer 300 may be configured to selectively optically couple the photonic component 21 to the photonic component 22, the photonic component 23, or the photonic component 24. In some arrangements, the photonic components 21, 22, 23 and 24 are arranged side by side, and the optical interposer 300 is configured to switch between optical paths (e.g., optical paths P2, P3, and P4) for optical transmission between any two of the photonic components 21, 22, 23 and 24.

In some arrangements, the optical interposer 300 includes a waveguide 310 (also referred to as “a patterned waveguide”) and an optical coupling mechanism 340. In some arrangements, the waveguide 310 includes a plurality of waveguide layers (e.g., waveguide layers 311, 312, and 313) that are configured to define at least two of the optical paths P2, P3, and P4.

In some arrangements, the optical coupling mechanism 340 is configured to control a coupling between the waveguide layer 311 and the waveguide layer 312. In some arrangements, the optical coupling mechanism 340 is configured to apply a voltage to a coupling region CIA between the waveguide layer 311 and the waveguide layer 312 to adjust a refractive index of a portion of the waveguide layer 311 and/or a refractive index of a portion of the waveguide layer 312.

In some arrangements, the optical coupling mechanism 340 includes electrodes 341, 342 and 343 that are disposed in the coupling region CIA. In some arrangements, the electrodes 341, 342 and 343 define a coverage of the coupling region CIA. In some arrangements, the electrodes 341 and 342 are disposed on two opposite sides of a portion of the waveguide layer 311, and the electrodes 342 and 343 are disposed on two opposite sides of a portion of the waveguide layer 312. A voltage may be applied to the electrode 341 to adjust the refractive index of the corresponding portion of the waveguide layer 311, and a voltage may be applied to the electrode 343 to adjust the refractive index of the corresponding portion of the waveguide layer 312. The electrode 342 may be referred to as a common electrode (or a source electrode). By selectively applying a voltage to at least one of the electrodes 341 and 343, the optical signal from the photonic component 21 may be transmitted to the photonic component 22 through the optical path P2 or to the photonic component 24 through the optical path P4. The optical path P2 may extend in the direction D1, and the optical path P4 may extend in a direction D3 (also referred to as “a horizontal direction”) that is substantially perpendicular to the direction D1 and the direction D2. In some other arrangements, the optical coupling mechanism 340 is configured to change a temperature of a coupling region CIA to adjust a refractive index of a portion of the waveguide layer 311 and/or a refractive index of a portion of the waveguide layer 312.

In some arrangements, the optical coupling mechanism 340 is configured to control a coupling between the waveguide layer 312 and the waveguide layer 313. In some arrangements, the optical coupling mechanism 340 is configured to apply a voltage to a coupling region C1B between the waveguide layer 312 and the waveguide layer 313 to adjust a refractive index of a portion of the waveguide layer 312 and/or a refractive index of a portion of the waveguide layer 313.

In some arrangements, the optical coupling mechanism 340 includes electrodes 341, 342 and 343 that are disposed in the coupling region C1B. In some arrangements, the electrodes 341, 342 and 343 define a coverage of the coupling region C1B. In some arrangements, the electrodes 341 and 342 are disposed on two opposite sides of a portion of the waveguide layer 312, and the electrodes 342 and 343 are disposed on two opposite sides of a portion of the waveguide layer 313. A voltage may be applied to the electrode 341 to adjust the refractive index of the corresponding portion of the waveguide layer 312, and a voltage may be applied to the electrode 343 to adjust the refractive index of the corresponding portion of the waveguide layer 313. The electrode 342 may be referred to as a common electrode (or a source electrode). By selectively applying a voltage to at least one of the electrodes 341 and 343, the optical signal from the photonic component 21 may be transmitted to the photonic component 24 through the optical path P4 or to the photonic component 23 through the optical path P3. In some other arrangements, the optical coupling mechanism 340 is configured to change a temperature of a coupling region C1B to adjust a refractive index of a portion of the waveguide layer 312 and/or a refractive index of a portion of the waveguide layer 313.

In some arrangements, one or more portions of the waveguide 310 and/or the ring resonators that are subject to an applied voltage so as to adjust the refractive index thereof includes a material having an electrical optic coefficient greater than about 30 pm/V. In some arrangements, portions of the waveguides 310 and 320 and the optical vias 330 that are not configured to be applied by a voltage to adjust the refractive index thereof does not require including a material having an electrical optic coefficient greater than about 30 pm/V.

According to some arrangements of the present disclosure, with the design of the optical interposer configured to switch between different optical paths for transmitting optical signals, optical couplings may be provided between various photonic components at different locations or even at different elevations by simply switching the optical paths. Therefore, the flexibility of packaging can be increased, and thus the yield can be improved.

In addition, according to some arrangements of the present disclosure, different optical paths can share one or more same portions of the waveguides and/or the optical vias. For example, the optical paths P1 and P2 both pass through (or share) a portion of the waveguide layer 311, and the optical paths P3 and P4 both pass through (or share) a portion of the waveguide layer 312. Therefore, compared to the cases where different optical paths are formed by completely different and separate waveguide structures, the design of the optical paths that can share one or more same portions of the package structure is advantageous to reducing the overall size of the optoelectronic package structure.

Moreover, according to some arrangements of the present disclosure, with the design of the recesses of the photonic component, the electronic components can be embedded in the photonic component, and thus the thickness of the optical interposer can be reduced accordingly. Therefore, the overall size of the optoelectronic package structure can be reduced. In addition, the electronic component may be electrically connected to the RDL within the recess of the photonic component, and thus the electrical path between the electronic component and the photonic component is significantly reduced.

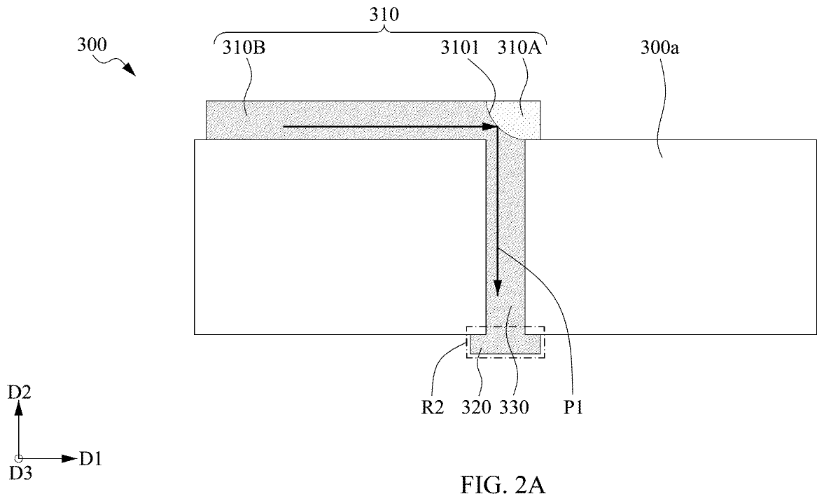

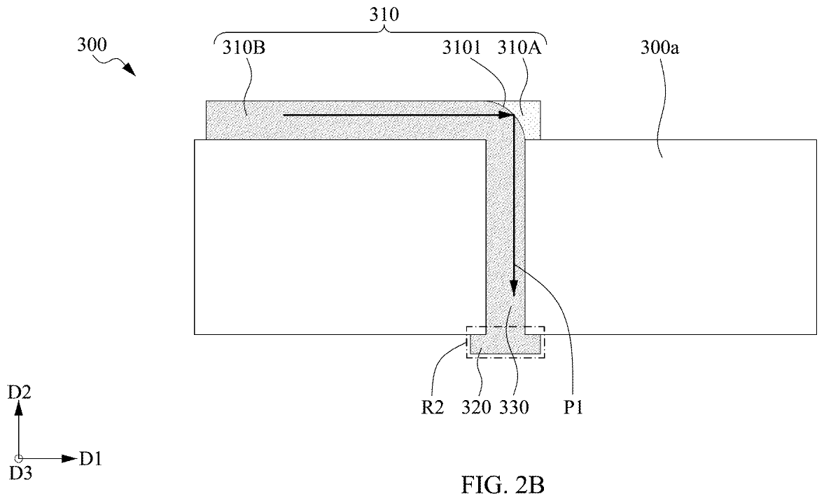

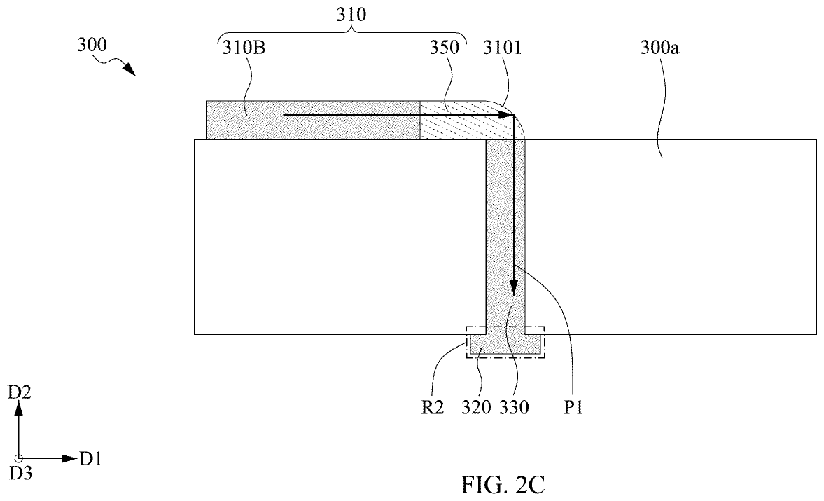

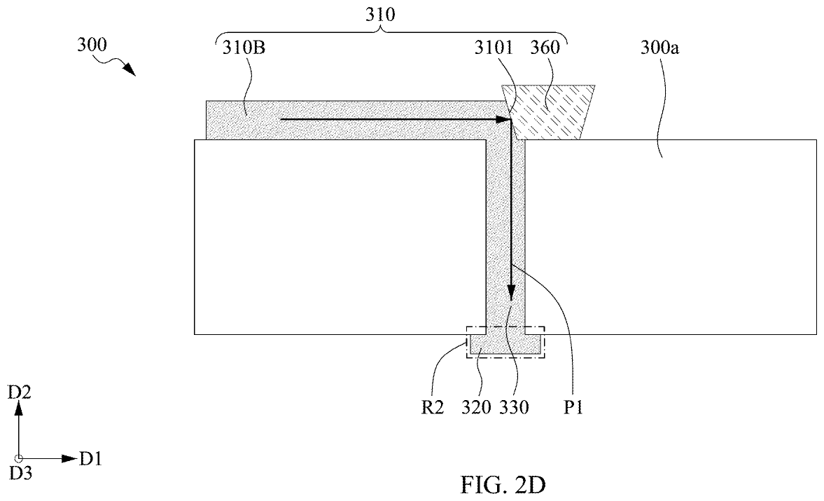

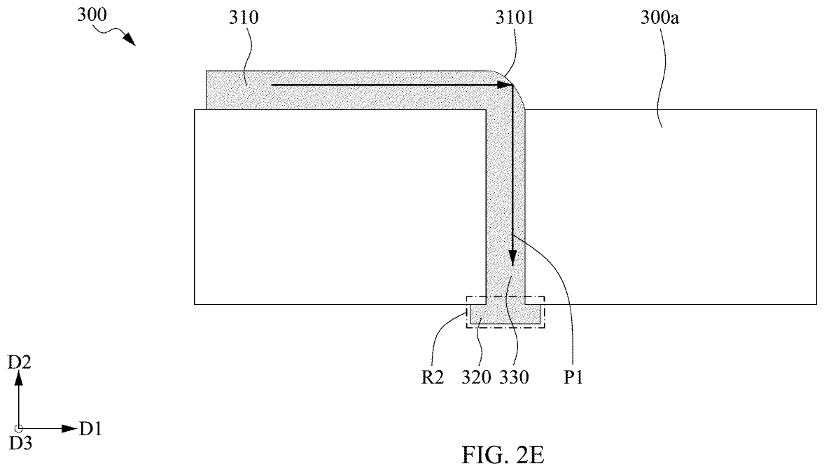

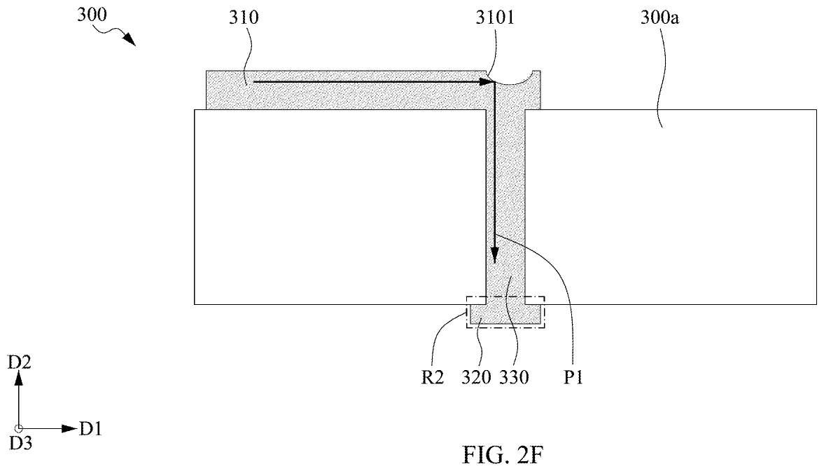

FIG. 2A is a cross-section of a portion of an optoelectronic package structure in accordance with some arrangements of the present disclosure. In some arrangements, FIG. 2A is a cross-section of a portion of the optoelectronic package structure 1A in FIG. 1A.

In some arrangements, the waveguide 310 defines an inclined reflective surface 3101 directly above the optical via 330. In some arrangements, the waveguide 310 includes a portion 310B contacting the optical via 330 and a portion 310A contacting the portion 310B to define the inclined reflective surface 3101. In some arrangements, a refractive index of the portion 310A is less than a refractive index of the portion 310B. In some arrangements, the inclined reflective surface 3101 defined by the portion 310A having a relatively low refractive index is configured to define the optical path P1 from the portion 310B of the waveguide 310 toward the optical via 330. In some arrangements, a portion of the optical via 330 and a portion of the waveguide 320 define the coupling region R2. The portion 310A may be or include a doped region. In some arrangements, with the portion 310A being a doped region, the optical coupling efficiency between the portion 310B and the optical via 330 is 86% or greater. In some arrangements, the portion 310B may have a refractive index equal or exceeding about 2.0, about 2.2, about 3, or about 3.5, and the portion 310A may have a refractive index less than about 2.0, about 1.8, about 1.5, or about 1. In some arrangements, the inclined reflective surface 3101 is a curved surface concave toward the portion 310B.

FIG. 2B is a cross-section of a portion of an optoelectronic package structure in accordance with some arrangements of the present disclosure. In some arrangements, FIG. 2B is a cross-section of a portion of the optoelectronic package structure 1A in FIG. 1A.

In some arrangements, the inclined reflective surface 3101 is a curved surface concave toward the portion 310A. According to some arrangements of the present disclosure, with the design of the inclined reflective surface 3101 serving as a concave mirror for the optical signal, the optical signal may be converged when redirecting toward the optical via 330. Therefore, the intensity of the optical signal may be improved.

FIG. 2C is a cross-section of a portion of an optoelectronic package structure in accordance with some arrangements of the present disclosure. In some arrangements, FIG. 2C is a cross-section of a portion of the optoelectronic package structure 1A in FIG. 1A.

In some arrangements, the waveguide 310 includes the portion 310B and a portion 350 connecting the portion 310B to the optical via 330. In some arrangement, the portion 350 of the waveguide 310 defines the inclined reflective surface 3101. The inclined reflective surface 3101 may be exposed to air. In some arrangements, the portion 350 is or includes a waveguide layer having a refractive index equal or exceeding about 2.0, about 2.2, about 3, or about 3.5. In some arrangements, the refractive index of the portion 350 is equal to or greater than the refractive index of the portion 310B.

FIG. 2D is a cross-section of a portion of an optoelectronic package structure in accordance with some arrangements of the present disclosure. In some arrangements, FIG. 2D is a cross-section of a portion of the optoelectronic package structure 1A in FIG. 1A.

In some arrangements, the waveguide 310 includes the portion 310B contacting the optical via 330 and a portion 360 contacting the portion 310B to define the inclined reflective surface 3101. In some arrangements, a refractive index of the portion 360 is less than a refractive index of the portion 310B. In some arrangements, the inclined reflective surface 3101 defined by the portion 360 having a relatively low refractive index is configured to define the optical path P1 from the portion 310B of the waveguide 310 toward the optical via 330. The portion 360 may be or include a material layer having an inverted trapezoidal cross-sectional profile. The portion 360 may be or include a dielectric layer, a conductive layer, or any suitable low-refractive index layer. In some arrangements, the portion 360 may have a refractive index less than about 2.0, about 1.8, about 1.5, or about 1.

FIG. 2E is a cross-section of a portion of an optoelectronic package structure in accordance with some arrangements of the present disclosure. In some arrangements, FIG. 2E is a cross-section of a portion of the optoelectronic package structure 1A in FIG. 1A.

In some arrangements, the waveguide 310 directly connects to the optical via 330 and defines the inclined reflective surface 3101. The inclined reflective surface 3101 may be exposed to air. The inclined reflective surface 3101 may be configured as a concave mirror for the optical signal to reduce or mitigate a loss in the intensity when transmitting the optical signal through the optical path P1. In some arrangements, with the inclined reflective surface 3101 exposed to air, the optical coupling efficiency between the portion 310 and the optical via 330 is 97% or greater.

FIG. 2F is a cross-section of a portion of an optoelectronic package structure in accordance with some arrangements of the present disclosure. In some arrangements, FIG. 2F is a cross-section of a portion of the optoelectronic package structure 1A in FIG. 1A.

In some arrangements, the waveguide 310 directly connects to the optical via 330 and defines the inclined reflective surface 3101. The inclined reflective surface 3101 may be exposed to air. The waveguide 310 may have a recess, and the inclined reflective surface 3101 may be defined by an inner surface of the recess.

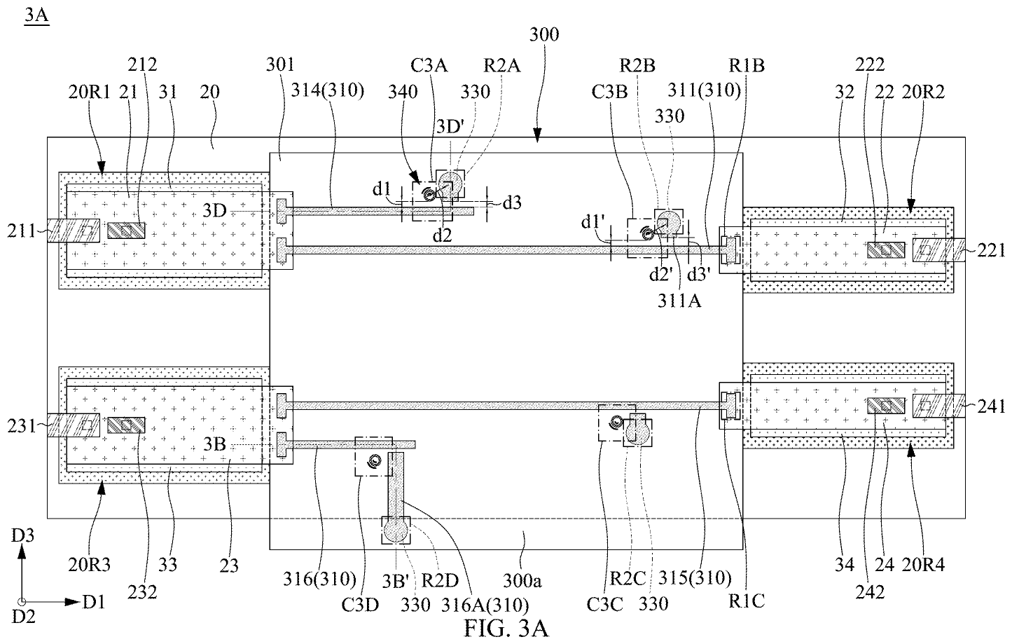

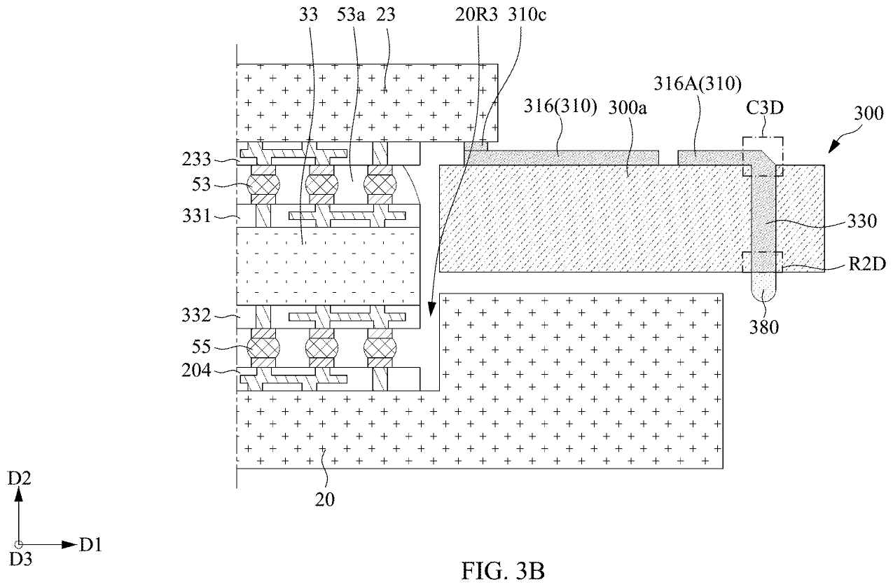

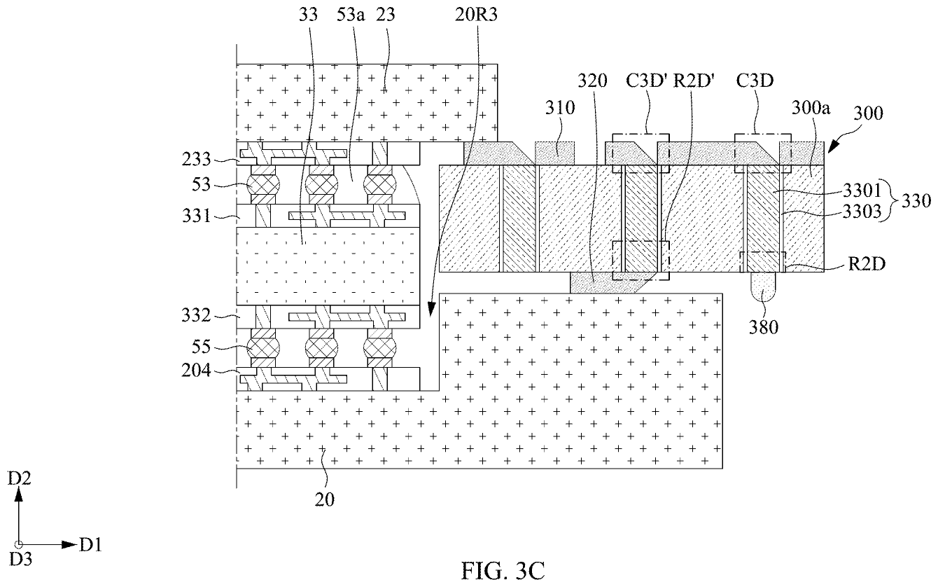

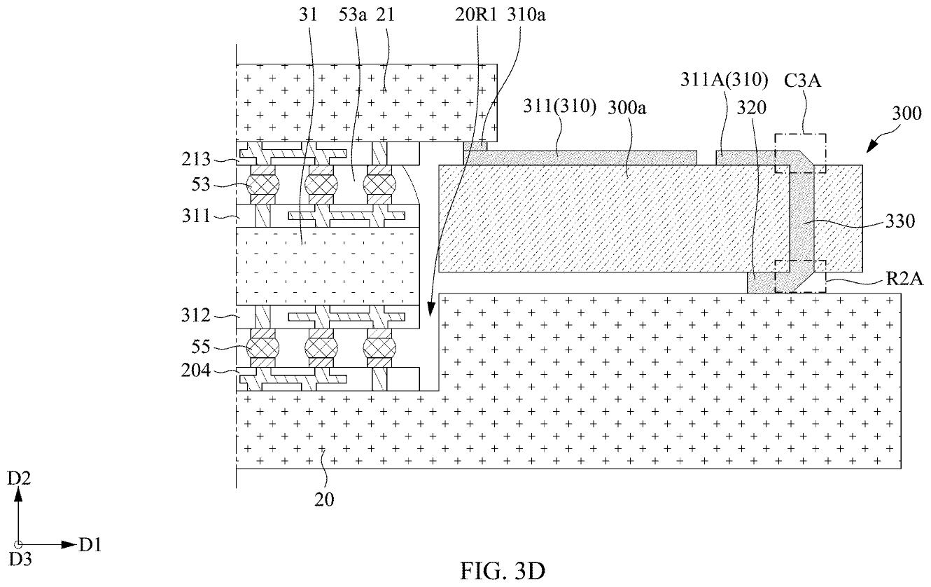

FIG. 3A is a top view of an optoelectronic package structure 3A in accordance with some arrangements of the present disclosure.

In some arrangements, the optical coupling mechanism 340 is configured to control a coupling between the waveguide 310 and one or more optical vias 330. In some arrangements, the optical coupling mechanism 340 is configured to apply a voltage to one or more coupling regions (e.g., coupling regions C3A, C3B, C3C, and C3D) or change a temperature of one or more coupling regions (e.g., coupling regions C3A, C3B, C3C, and C3D) to adjust the refractive index of the one or more coupling regions. In some arrangements, the optical coupling mechanism 340 is configured to adjust a refractive index of one or more coupling regions (e.g., coupling regions C3A, C3B, C3C, and C3D) between the waveguide 310 and the optical via(s) 330. In some arrangements, the optical coupling mechanism 340 is configured to control a coupling between the waveguide 310 and the optical via(s) 330.

In some arrangements, the optical coupling mechanism 340 includes one or more ring resonators optically coupling the waveguide 310 to the optical via 330. In some arrangements, the waveguide 310 is spaced apart from the optical via 330 by the ring resonator. In some arrangements, the ring resonator includes a material having an electrical optic coefficient greater than about 30 pm/V. In some arrangements, the ring resonator is over the surface 301.

In some arrangements, the optical coupling mechanism 340 is configured to apply a voltage to a ring resonator of the coupling region C3A to adjust the refractive index of the ring resonator to optically couple the waveguide layer 314 of the waveguide 310 to the optical via 330. An optical signal from the photonic component 21 may be transmitted to the optical via 330 and optically coupled to the photonic component 20 through the coupling region R2A. In some arrangements, the ring resonator is spaced apart from the waveguide layer 314 by a distance d1, and the ring resonator is spaced apart from the conductive via 330 or an extension of the conductive via 330 by a distance d2. In some arrangements, the waveguide layer 314 is spaced apart from the conductive via 330 or an extension of the conductive via 330 by a distance d3. In some arrangements, the distances d1, d2, and d3 are substantially the same.

In some arrangements, the optical coupling mechanism 340 is configured to apply a voltage to a ring resonator of the coupling region C3B to adjust the refractive index of the ring resonator to control the optical coupling between the waveguide layer 311 of the waveguide 310 and the optical via 330. An optical signal from the photonic component 21 may be transmitted to the optical via 330 and optically coupled to the photonic component 20 through the coupling region R2B or transmitted to the photonic component 22 through the coupling region RIB depending on whether the ring resonator optically couples the waveguide layer 311 of the waveguide 310 to the optical via 330 or not. In some arrangements, the ring resonator is spaced apart from the waveguide layer 311 by a distance d1′, and the ring resonator is spaced apart from the conductive via 330 or an extension of the conductive via 330 by a distance d2′. In some arrangements, the waveguide layer 311 is spaced apart from the conductive via 330 or an extension of the conductive via 330 by a distance d3′. In some arrangements, the distances d1′ and d2′ are substantially the same. In some arrangements, the distance d3′ is greater than the distances d1′ and d2′. With the design of the distances d1′, d2′, and d3′, the relatively large distance d3′ can prevent undesired optical coupling between the conductive via 330 and the waveguide layer 311, such that the transmission loss of the optical signal transmitted to the photonic component 22 can be reduced, and the directional selectivity of optical coupling can be increased.

In some arrangements, the optical coupling mechanism 340 is configured to apply a voltage to a ring resonator of the coupling region C3C to adjust the refractive index of the ring resonator to control the optical coupling between the waveguide layer 315 of the waveguide 310 and the optical via 330. An optical signal from the photonic component 23 may be transmitted to the optical via 330 and optically coupled to the photonic component 20 through the coupling region R2C or transmitted to the photonic component 24 through the coupling region R1C depending on whether the ring resonator optically couples the waveguide layer 315 of the waveguide 310 to the optical via 330 or not.

In some arrangements, the optical coupling mechanism 340 is configured to apply a voltage to a ring resonator of the coupling region C3D to adjust the refractive index of the ring resonator to optically couple the waveguide layer 316 of the waveguide 310 to the optical via 330. An optical signal from the photonic component 23 may be transmitted to the optical via 330 and output through the coupling region R2D.

FIG. 3B is a cross-section of an optoelectronic package structure in accordance with some arrangements of the present disclosure. In some arrangements, FIG. 3B is a cross-section along a line 3B-3B′ in FIG. 3A.

In some arrangements, the optical interposer 300 further includes an optical lens 380 contacting the coupling region R2. In some arrangements, an optical signal may be transmitted from the photonic component 23 to the waveguide layer 316 through an optical contact 310c. In some arrangements, also referring to FIG. 3A, the optical signal from the photonic component 23 may be optically coupled to the waveguide layer 316A, transmitted to the optical via 330, and output through the coupling region R2D and the optical lens 380.

In some arrangements, the electronic component 33 includes RDLs 331 and 332 that are electrically connected to each other through conductive vias (not shown in FIG. 3B). In some arrangements, the electronic component 33 is flip-chip bonded to the photonic component 23. In some arrangements, the RDL 331 is electrically connected to the RDL 233 of the photonic component 23 through connection elements 53. In some arrangements, the RDL 332 is electrically connected to the RDL 204 of the photonic component 20 through connection elements 55.

In some arrangements, the optical vias 330 may be or include silicon, silicon nitride (Si₃N₄), lithium niobate (LiNbO₃), lithium tantalite (LiTiO₃), or a combination thereof. In some arrangements, the base layer 300a may be or include glass. In some embodiments, the optical vias 330 contact the base layer 300a.

FIG. 3C is a cross-section of an optoelectronic package structure in accordance with some arrangements of the present disclosure. In some arrangements, FIG. 3B is a cross-section of a portion of the optoelectronic package structure 3A in FIG. 3A. The structure illustrated in FIG. 3C is similar to that in FIG. 3B, and the differences therebetween are described as follows.

In some arrangements, the optical via 330 includes a core 3301 and a cladding layer 3303 separating the core 3301 from the base layer 300a. In some arrangements, the core 3301 has a refractive index greater than a refractive index of the cladding layer 3303. In some arrangements, the core 3301 may be or include silicon, silicon nitride (Si₃N₄), lithium niobate (LiNbO₃), lithium tantalite (LiTiO₃), or a combination thereof. In some arrangements, the base layer 300a may be or include an organic substrate or a two-layer substrate which includes a core layer and a conductive material and/or structure disposed on an upper surface and a bottom surface thereof.

In some arrangements, the optical coupling mechanism 340 is configured to apply a voltage to a ring resonator (not shown in FIG. 3C) of the coupling region C3D′ to optically couple the waveguide 310 to the optical via 330 to transmit an optical signal from the photonic component 23 to the photonic component 20 through the coupling region R2D′ to the waveguide 320. In some arrangements, a portion of the optical via 330 and a portion of the waveguide 320 define the coupling region R2D′.

FIG. 3D is a cross-section of an optoelectronic package structure in accordance with some arrangements of the present disclosure. In some arrangements, FIG. 3D is a cross-section along a line 3D-3D′ in FIG. 3A.

In some arrangements, also referring to FIG. 3A, the optical signal from the photonic component 21 may be optically coupled to the waveguide layer 311A and transmitted to the optical via 330. In some arrangements, the photonic component 20 is optically coupled to the coupling region R2A.

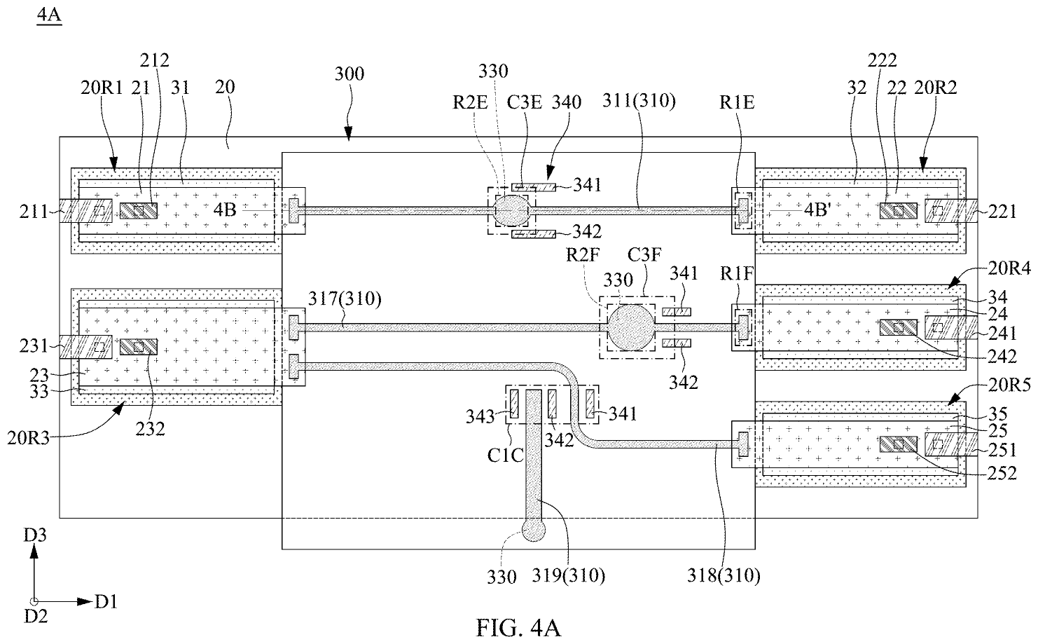

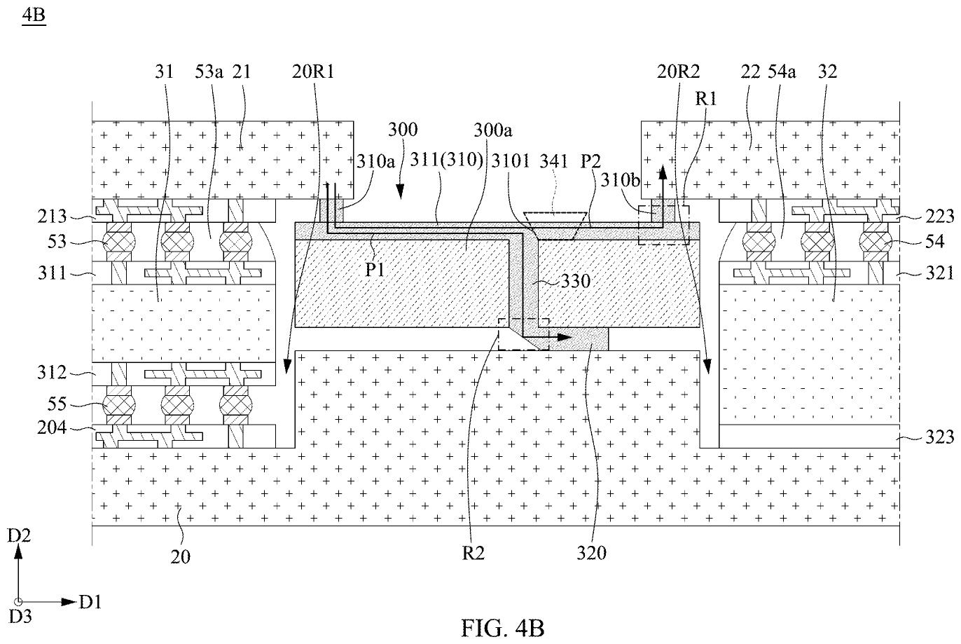

FIG. 4A is a top view of an optoelectronic package structure 4A in accordance with some arrangements of the present disclosure. The optoelectronic package structure 4A may include photonic components 20, 21, 22, 23, 24, and 25, electronic components 31, 32, 33, 34, and 35, and an optical interposer 300. In some arrangements, the photonic component 25 includes optical components 251 and 252. The photonic component 25 is similar to the photonic components 21 and 22, the optical components 251 and 252 are similar to the optical components 211 and 212, the electronic component 35 is similar to the electronic components 31 and 32, and the description thereof is omitted hereinafter. It should be noted that the numbers of the photonic components, electronic components, and/or other components may vary according to actual applications and are not limited thereto.

In some arrangements, the optical coupling mechanism 340 is configured to control a coupling between the waveguide 310 and one or more optical vias 330. In some arrangements, the optical coupling mechanism 340 is configured to apply a voltage to one or more coupling regions (e.g., coupling regions C3E, C3F, and C1C) or change a temperature of one or more coupling regions (e.g., coupling regions C3E, C3F, and C1C) to adjust the refractive index of the one or more coupling regions. In some arrangements, the optical coupling mechanism 340 is configured to adjust a refractive index of one or more coupling regions (e.g., coupling regions C3E, C3F, and C1C) between the waveguide 310 and the optical via(s) 330. In some arrangements, the optical coupling mechanism 340 is configured to control a coupling between the waveguide 310 and the optical via(s) 330.

In some arrangements, the optical coupling mechanism 340 includes electrodes around one or more coupling regions (e.g., coupling regions C3E, C3F, and C1C) between the waveguide 310 and the optical via(s) 330. One or more optical vias 330 may contact the waveguide 310.

In some arrangements, the waveguide 310 includes a plurality of waveguide layers (e.g., waveguide layers 311, 317, 318, and 319). In some arrangements, the optical coupling mechanism 340 includes electrodes on opposite sides of at least a portion of the waveguide 310, and the portion of the waveguide 310 includes a material having an electrical optic coefficient greater than about 30 pm/V.

In some arrangements, the optical coupling mechanism 340 is configured to apply a voltage to the electrode 341 of the coupling region C3E to adjust the refractive index of a portion of the waveguide layer 311 between the electrodes 341 and 342. An optical signal from the photonic component 21 may be transmitted to the optical via 330 and optically coupled to the photonic component 20 through the coupling region R2E or transmitted to the photonic component 22 through the coupling region R1E. The aforesaid situation depends on whether the portion of the waveguide layer 311 between the electrodes 341 and 342 generates a reflective inclined surface (referring to FIGS. 2A-2F) that stops the transmission of the optical signal to the photonic component 22 or not.

In some arrangements, the optical coupling mechanism 340 is configured to apply a voltage to the electrode 341 of the coupling region C3F to adjust the refractive index of a portion of the waveguide layer 317 between the electrodes 341 and 342. An optical signal from the photonic component 22 may be transmitted to the optical via 330 and optically coupled to the photonic component 20 through the coupling region R2F or transmitted to the photonic component 24 through the coupling region RIF. The aforesaid situation depends on whether the portion of the waveguide layer 317 between the electrodes 341 and 342 generates a reflective inclined surface (referring to FIGS. 2A-2F) that stops the transmission of the optical signal to the photonic component 24 or not.

In some arrangements, the optical coupling mechanism 340 is configured to apply a voltage to a coupling region C1C between the waveguide layer 318 and the waveguide layer 319 to adjust a refractive index of a portion of the waveguide layer 318 and/or a refractive index of a portion of the waveguide layer 319. An optical signal from the photonic component 22 may be optically coupled to the waveguide layer 319 through the coupling region C1C and transmitted to the optical via 330 to output from the optical interposer 300 or transmitted to the photonic component 25 along the waveguide layer 318. The aforesaid situation depends on whether the waveguide layer 318 optically couples to the waveguide layer 319 at the coupling region C1C or not.

FIG. 4B is a cross-section of an optoelectronic package structure in accordance with some arrangements of the present disclosure. In some arrangements, FIG. 4B is a cross-section along a line 4B-4B′ in FIG. 4A.

It should be noted that the electrode 341 is indicated by dashed lines in FIG. 4B to show the relative positions of the electrode 341 and the waveguide layer 311 of the waveguide 310. In some arrangements, the electrodes 341 and 342 (not shown in FIG. 4B) may have an inverted trapezoidal cross-sectional profile. In some arrangements, when a voltage is applied to the electrode 341 to reduce the refractive index of a portion of the waveguide layer 311 between the electrodes 341 and 342, the low-refractive index portion may have a boundary that substantially aligns with an edge of the electrode 341. The boundary may be an interface between the low-refractive index portion and a portion of the waveguide layer 311 that is not between electrodes 341 and 342 or exposed from the electrodes 341 and 342. Therefore, such boundary or interface defines an inclined reflective surface 3101 of the waveguide layer 311 directly over the optical via 330.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3º, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some arrangements, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific arrangements thereof, these descriptions and illustrations do not limit the present disclosure. It can be clearly understood by those skilled in the art that various changes may be made, and equivalent components may be substituted within the arrangements without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An optoelectronic package structure, comprising:
a first photonic component; and
an optical interposer comprising a plurality of optical paths and optically coupled to the first photonic component, wherein the optical interposer is configured to switch between the optical paths for transmitting an optical signal from the first photonic component.

2. The optoelectronic package structure as claimed in claim 1, further comprising a second photonic component and a third photonic component, wherein the optical interposer is configured to switch between the optical paths for transmitting the optical signal from the first photonic component to the second photonic component or the third photonic component.

3. The optoelectronic package structure as claimed in claim 2, wherein the plurality of optical paths comprises a first optical path along a vertical direction and a second optical path along a horizontal direction, and the optical interposer is configured to switch between the first optical path and the second optical path for transmitting the optical signal to the second photonic component or the third photonic component.

4. The optoelectronic package structure as claimed in claim 3, wherein the optical interposer comprises a waveguide, and the first optical path and the second optical path partially overlap in the waveguide.

5. The optoelectronic package structure as claimed in claim 2, wherein the first photonic component and the third photonic component are arranged side by side, and the optical interposer is configured to support the first photonic component and the third photonic component.

6. The optoelectronic package structure as claimed in claim 2, wherein the first photonic component is disposed over the second photonic component, and the optical interposer comprises an optical via configured to transmit the optical signal through a first optical path of the plurality of optical paths from the first photonic component to the second photonic component.

7. The optoelectronic package structure as claimed in claim 6, wherein the third photonic component is disposed over the second photonic component, and the optical interposer comprises a waveguide configured to transmit the optical signal through a second optical path of the plurality of optical paths from the first photonic component to the third photonic component.

8. The optoelectronic package structure as claimed in claim 1, wherein the optical interposer comprises:
a waveguide extending in a first direction;
an optical via extending in a second direction substantially perpendicular to the first direction; and
an optical coupling mechanism configured to control a coupling between the waveguide and the optical via.

9. The optoelectronic package structure as claimed in claim 8, wherein the optical coupling mechanism comprises a ring resonator optically coupling the waveguide to the optical via, and the waveguide is spaced apart from the optical via by the ring resonator.

10. The optoelectronic package structure as claimed in claim 8, wherein the optical coupling mechanism comprises electrodes around a coupling region between the waveguide and the optical via, and the optical via contacts the waveguide.

11. The optoelectronic package structure as claimed in claim 1, further comprising:
a second photonic component disposed under the first photonic component; and
an electronic component at least partially embedded in the second photonic component, wherein the electronic component is configured to process a first electrical signal from the first photonic component and a second electrical signal from the second photonic component.

12. The optoelectronic package structure as claimed in claim 11, wherein a depth of the electronic component embedded in the second photonic component is configured to adjust a thickness of the optical interposer.

13. An optoelectronic package structure, comprising:
a first photonic component; and
an optical interposer having a first surface and a second surface opposite to the first surface, wherein the optical interposer is configured to receive an optical signal from the first photonic component and switch between a first coupling region at the first surface and a second coupling region at the second surface to output the optical signal.

14. The optoelectronic package structure as claimed in claim 13, wherein the optical interposer comprises a first waveguide adjacent to the first surface, and the first waveguide comprises the first coupling region.

15. The optoelectronic package structure as claimed in claim 14, wherein the optical interposer further comprises a second waveguide adjacent to the second surface and an optical via extending between the first waveguide and the second waveguide, the second waveguide comprises the second coupling region, and the optoelectronic package structure further comprises a second photonic component optically coupled to the second coupling region.

16. An optoelectronic package structure, comprising:
a first photonic component and a second photonic component disposed over a third photonic component; and
an optical interposer configured to selectively optically couple the first photonic component to the second photonic component or the third photonic component.

17. The optoelectronic package structure as claimed in claim 16, wherein the third photonic component has a recess recessed from an upper surface of the third photonic component, and the optoelectronic package structure further comprises an electronic component disposed in the recess.

18. The optoelectronic package structure as claimed in claim 17, wherein the optical interposer is free from overlapping the recess along a vertical direction.

19. The optoelectronic package structure as claimed in claim 16, wherein the optical coupling mechanism comprises electrodes on opposite sides of a portion of the waveguide, and the portion of the waveguide comprises a material having an electrical optic coefficient greater than about 30 pm/V.

20. The optoelectronic package structure as claimed in claim 19, wherein the electrodes has an inverted trapezoidal cross-sectional profile.
